(19) United States
(12) Patent Application Publication
(10) Pub. No.: US 2005/0135468 A1
(43) Pub. Date: Jun. 23, 2005

(54) Feed forward filter

(76) Inventors: Bhushan Asuri, Oak Park, CA (US); Anush A. Krishnaswami, San Diego, CA (US); William J. Chimitt, Folsom, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/741,039

(22) Filed: Dec. 19, 2003

(51) Int. Cl. H03K 5/159

(52) U.S. Cl. 375/232; 375/350

(57) ABSTRACT

Disclosed are a multi-tap filter, and method of using same, to filter an analog input signal to provide an equalized analog signal. Each of a plurality of coefficients in the multi-tap filter may be updated based, at least in part, upon a comparison of the equalized analog signal with one or more symbol values at an instance determined by inter-symbol timing information.

### RELATED MATTERS

The subject matter disclosed herein relates to U.S. patent application Ser. Nos. (attorney docket numbers 042390.P17559, 042390.P18170, 042390.P17154 and 042390.P 17155), filed concurrently with the present application and incorporated herein by reference.

### BACKGROUND

1. Field

The subject matter discloses herein relates to devices and methods of processing data received from a transmission medium. In particular, the subject matter disclosed herein relates to processing signals received from a communication channel in the presence of noise and distortion.

2. Information

To recover information from a signal received from noisy communication channel, receivers typically employ filtering and equalization techniques to enable reliable detection of the information. Decreases in the cost of digital circuitry have enabled the cost effective use of adaptive digital filtering and equalization techniques that can optimally “tune” a filter according to the specific characteristics of a noisy communication channel.

FIG. 1 shows a conventional digital filter 10 employing a finite impulse response (FIR) configuration. An analog input signal 12 is received at an analog to digital converter (ADC) 14 to provide a digital signal at discrete sample intervals. The analog input signal 12 may be transmitting encoded symbols representing information in a noisy communication channel with distortion. The ADC 14 may sample the analog input signal at discrete sample intervals corresponding with an inter-symbol temporally spacing or fractions thereof. On each discrete sample interval, the digital signal from the present discrete sample interval is provided to a multiplication circuit 20 to be scaled by coefficient c₀, and signal taps from delay circuits 16 and 26 are provided to multiplication circuits 20 to be scaled by coefficients c₂ and c₄, respectively. The outputs of the three multiplication circuits are then additively combined at a summing circuit 22 as a filtered output signal.

The coefficients c₀, c₂ and c₄ are typically updated to approximate a least mean square error (LMS) filter for the particular FIR filter configuration. A limiting circuit 30 may provide a bi-level detection of symbols in the equalized output from the summing circuit 22 and differencing circuit 28 may provide a difference between the filtered output and the detected symbol as an “error.” A limiting circuit 26 provides a sign of the error to each of three multiplication circuits 25 for updating the coefficients c₀, c₂ and c₄. Each of the multiplication circuits 25 multiplies the sign of the error with the sign of a corresponding signal tap of the digital signal (as detected at a limiting circuit 18) and a sample and integrating circuit 24 generates an updated coefficient.

### BRIEF DESCRIPTION OF THE FIGURES

Non-limiting and non-exhaustive embodiments of the present invention will be described with reference to the following figures, wherein like reference numerals refer to like parts throughout the various figures unless otherwise specified.

FIG. 1 shows a conventional digital filter employing a finite impulse response configuration.

FIG. 2 shows a schematic diagram of a receiver according to an embodiment of the present invention.

FIG. 3 shows a schematic diagram of a feed forward filter according to an embodiment of the receiver shown in FIG. 2.

FIG. 4 shows a schematic diagram of a circuit to generate the sign of an error according to an embodiment of the error generation circuit shown in FIG. 3.

FIG. 5 shows a schematic diagram of a circuit to update coefficients of a finite impulse response filter according to an embodiment of the feed forward filter shown in FIG. 3.

FIG. 6 shows a schematic diagram of a charge pump circuit according to an embodiment of the circuit shown in FIG. 5.

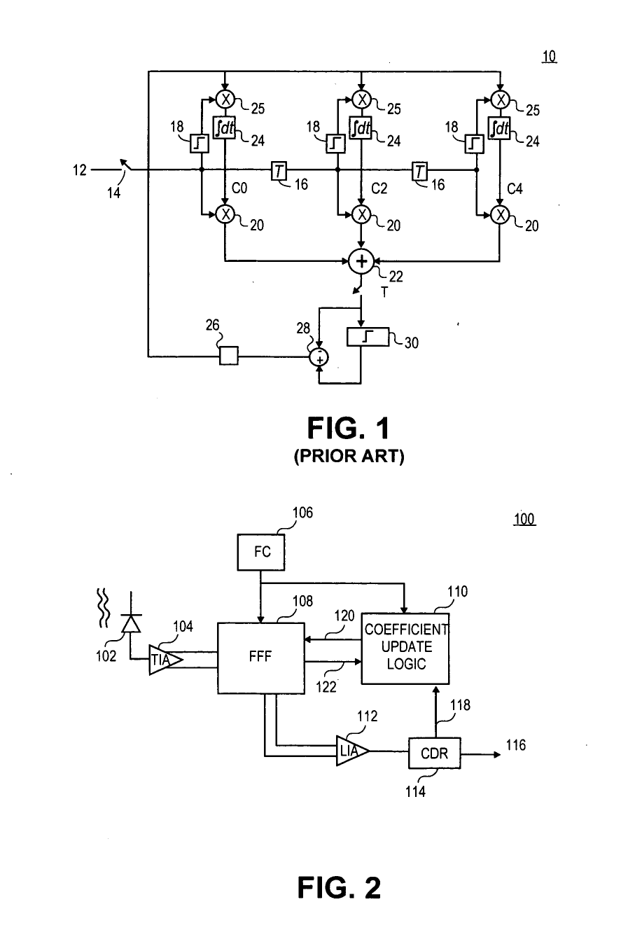

### DETAILED DESCRIPTION

Reference throughout this specification to “one embodiment” or “an embodiment” means that a particular feature, structure, or characteristic described in connection with the embodiment is included in at least one embodiment of the present invention. Thus, the appearances of the phrase “in one embodiment” or “an embodiment” in various places throughout this specification are not necessarily all referring to the same embodiment. Furthermore, the particular features, structures, or characteristics may be combined in one or more embodiments.

“Machine-readable” instructions as referred to herein relates to expressions which may be understood by one or more machines for performing one or more logical operations. For example, machine-readable instructions may comprise instructions which are interpretable by a processor compiler for executing one or more operations on one or more data objects. However, this is merely an example of machine-readable instructions and embodiments of the present invention are not limited in this respect.

“Machine-readable medium” as referred to herein relates to media capable of maintaining expressions which are perceivable by one or more machines. For example, a machine readable medium may comprise one or more storage devices for storing machine-readable instructions or data. Such storage devices may comprise storage media such as, for example, optical, magnetic or semiconductor storage media. However, this is merely an example of a machine-readable medium and embodiments of the present invention are not limited in this respect.

“Logic” as referred to herein relates to structure for performing one or more logical operations. For example, logic may comprise circuitry which provides one or more output signals based upon one or more input signals. Such circuitry may comprise a finite state machine which receives a digital input and provides a digital output, or circuitry which provides one or more analog output signals in response to one or more analog input signals. Such circuitry may be provided in an application specific integrated circuit (ASIC) or field programmable gate array (FPGA). Also, logic may comprise machine-readable instructions stored in a memory in combination with processing circuitry to execute such machine-readable instructions. However, these are merely examples of structures which may provide logic and embodiments of the present invention are not limited in this respect.

A “receiver” as referred to herein relates to a system, apparatus or circuit to process a signal received from a transmission medium. For example, a receiver may comprise circuitry or logic to extract information encoded in a signal received from a transmission medium. However, this is merely an example of a receiver and embodiments of the present invention are not limited in this respect.

An “analog signal” as referred to herein relates to a signal having a value that may change continuously over a time interval. For example, an analog signal may be associated with one or more voltages where each voltage may change continuously over a time interval. An analog signal may be sampled at discrete time intervals to provide a “digital signal” where one or more discrete signal values are associated with each discrete time interval and, unlike an analog signal, do not change continuously between such discrete time intervals. However, this is merely an example of an analog signal as contrasted from a digital signal and embodiments of the present invention are not limited in these respects.

A “symbol” as referred to herein relates to a representation of information encoded in a signal transmitted in a transmission medium. For example, a symbol may represent a “one” or “zero” in a single information “bit” or multiple bits according to a symbol mapping defined for transmitting information in a communication channel. Accordingly, a transmitted symbol may be associated with a “symbol value” as defined by the symbol mapping. Upon receipt of a signal transmitting an encoded symbol, a receiver may extract an “estimated symbol value” to represent an estimate of the symbol value of the actual symbol transmitted by the signal in the communication channel. In the presence of noise in the communication channel, an estimated symbol value may deviate from the symbol value of the actual symbol transmitted by an “error.” For a symbol value characterized as having a magnitude, an error associated with an estimated symbol value may be associated with a “sign” to represent whether the estimated symbol value exceeds or does not exceed the symbol value of the actual symbol transmitted. An “error signal” may be generated to provide information indicative of at least one aspect of a detected error. Such an error signal may include, for example, a sign of an error or a magnitude expressing a difference between a measured signal and an actual signal.

Symbols transmitted in a signal may be temporally spaced on “symbol” intervals such that during each distinct symbol interval the signal may transmit a corresponding symbol. An “equalized signal” as referred to herein relates to a signal that has been conditioned or processed. For example, a signal received from a communication channel in the presence of noise and distortion may be processed to enable or improve the detection of symbols being transmitted in the received signal. However, this is merely an example of an equalized signal and embodiments of the present invention are not limited in these respects.

A signal may be “tapped” to provide signal taps or delayed versions of a signal to be processed. A “multi-tap filter” as referred to herein relates to circuitry or logic to process a signal by individually processing the signal at distinct signal taps and combining the individually processed signal taps to provide an equalized signal. For example, a multi-tap filter may comprise one or more delay elements to generate one or more signal taps. An amplitude of each of the signal taps may then be scaled by a corresponding “coefficient.” The scaled versions of the signal taps may then be combined to provide an equalized output signal. However, this is merely an example of a multi-tap filter and embodiments of the present invention are not limited in these respects.

A “correlation signal” as referred to herein relates to a result of a combination of two or more signals. A correlation signal may be the result of a multiplication of two or more signals, or a result of a logical operation on the two or more signals as inputs. In one particular example, a correlation signal may be the result of a combination of an error signal and a data signal. However, this is merely an example of a correlation signal and embodiments of the present invention are not limited in these respects.

“Inter-symbol timing information” as referred to herein relates to information that indicates the timing of a signal transmitting encoded symbols at set symbol intervals. Such inter-symbol timing information may be transmitted in a clock signal having a period that is synchronized with a period of the symbol intervals in the signal transmitting the encoded symbols. However, this is merely an example of inter-symbol timing information and embodiments of the present invention are not limited in this respect.

A “clock and data recovery circuit” as referred to herein relates to a circuit that is capable of detecting data symbols encoded in a symbol and timing information. For example, a clock and data recovery circuit may detect symbols in an equalized signal and inter-symbol timing information that is synchronized to symbol intervals in the signal. The clock and data recovery circuit may then generate a clock signal that is synchronized with the inter-symbol timing information. However, this is merely an example of a clock and data recovery circuit, and embodiments of the present invention are not limited in these respects.

Briefly, embodiments of the present invention relate to a multi-tap filter to apply each of a plurality of coefficients to a corresponding tap of an analog input signal to generate an equalized analog signal. A coefficient update circuit may update the coefficients based, at least in part, upon a comparison of the equalized analog signal with one or more symbol values at an instance determined by inter-symbol timing information. However, this is merely an example embodiment and other embodiments of the present invention are not limited in these respects.

FIG. 2 shows a schematic diagram of a receiver 100 according to an embodiment of the present invention. A transimpedance amplifier 104 may receive a current signal from a photodiode 102 in response to exposure to light energy (e.g., from a fiber optic cable). The transimpedance amplifier 104 may convert the current signal into an analog input signal expressed as a voltage signal representing the intensity of light energy received at the photodiode 102. A feed forward filter (FFF) 108 may process the analog input signal using a multi-tap filter (not shown) to provide an equalized analog output signal to a limiting amplifier (LIA) 112. The LIA 112 may then map the equalized analog output signal to specific voltages in a range of voltages. A clock and data recovery (CDR) circuit 114 may associate the mapped voltages with symbols on symbol intervals which are provided at output 116, and generate inter-symbol timing information 118.

According to an embodiment, coefficient update logic 110 may provide periodically updated coefficients to the multi-tap filter based upon estimated errors in the detection of symbols from the equalized analog output signal and the inter-symbol timing information 118. The FFF 108 provides an equalized analog output signal from an analog input signal without digitally sampling the analog input signal. Accordingly, no analog to digital conversion of the analog input signal is needed prior to filtering at the multi-tap filter. A functional controller (FC) 106 may initialize coefficients in the FFF 108 and the coefficient update logic 110 at startup.

According to an embodiment, the FC 106 may control initial loop operation by disabling any dynamic operation of the coefficient update logic 110 and force the coefficients of FFF 108 to predetermined values. For example, the FC 106 may detect a dynamic condition (e.g., start up) and set the coefficients of the FFF 108 to the predetermined values. The FC 106 may then inhibit the coefficient update logic 110 from updating the coefficients from the predetermined values for a time period. In one embodiment, the FC 106 may enable the coefficient update logic 110 to update the coefficients in response to recovery of the inter-symbol timing information by the CDR circuit 114. Alternatively, the FC 106 may enable the coefficient update logic 110 to update the coefficients following a duration based upon an estimated time for CDR circuit 114 to recover the inter-symbol timing information.

While the receiver 100 is shown receiving an analog input signal from a photodiode and transimpedance amplifier, it should be understood that the architecture of receiver 100 may be adapted for processing an analog input signal from different transmission media. For example, other embodiments may be adapted for processing an analog input signal received as a differential signaling pair signal over unshielded twisted wire pair cabling or over a device to device interconnection formed in a printed circuit board. Other embodiments may be adapted to reading data from high density storage devices (e.g., optical storage media) to enable increased data storage density by equalizing distortion from the dense packing of bits on the high density devices. However, these are merely examples of how a receiver may be implemented for recovering information from a signal and embodiments of the present invention are not limited in these respects.

The receiver 100 may be included as part of an optical transceiver (not shown) to transmit or receive optical signals in an optical transmission medium such as fiber optic cabling. The optical transceiver may modulate a transmitted signal or demodulate a received signal 112 according to any optical data transmission format such as, for example, wave division multiplexing wavelength division multiplexing (WDM) or multi-amplitude signaling (MAS). For example, a transmitter portion of the optical transceiver may employ WDM for transmitting multiple “lanes” of data in the optical transmission medium.

The FFF 108 and LIA 112 may form a physical medium dependent (PMD) section of the receiver 100. Such a PMD section may also provide power from a laser driver circuit (not shown) to a laser device (not shown). The CDR circuit 114 may be included in a physical medium attachment section coupled to the PMD section. Such a PMA section may also include de-multiplexing circuitry (not shown) to recover data from a conditioned signal received from the PMD section, multiplexing circuitry (not shown) for transmitting data to the PMD section in data lanes, and a serializer/deserializer (Serdes) for serializing a parallel data signal from a layer 2 section (not shown) and providing a parallel data signal to the layer 2 section 108 based upon a serial data signal provided by the CDR circuit 114.

According to an embodiment, the layer 2 section may comprise a media access control (MAC) device coupled to the PMA section at a media independent interface (MII) as defined IEEE Std.802.3ae-2002, clause 46. In other embodiments, the layer 2 section may comprise forward error correction logic and a framer to transmit and receive data according to a version of the Synchronous Optical Network/Synchronous Digital Hierarchy (SONET/SDH) standard published by the International Telecommunications Union (ITU). However, these are merely examples of layer 2 devices that may provide a parallel data signal for transmission on an optical transmission medium, and embodiments of the present invention are not limited in these respects.

The layer 2 section may also be coupled to any of several input/output (I/O) systems (not shown) for communication with other devices on a processing platform. Such an I/O system may include, for example, a multiplexed data bus coupled to a processing system or a multi-port switch fabric. The layer 2 section may also be coupled to a multi-port switch fabric through a packet classification device. However, these are merely examples of an I/O system which may be coupled to a layer 2 device and embodiments of the present invention are not limited in these respects.

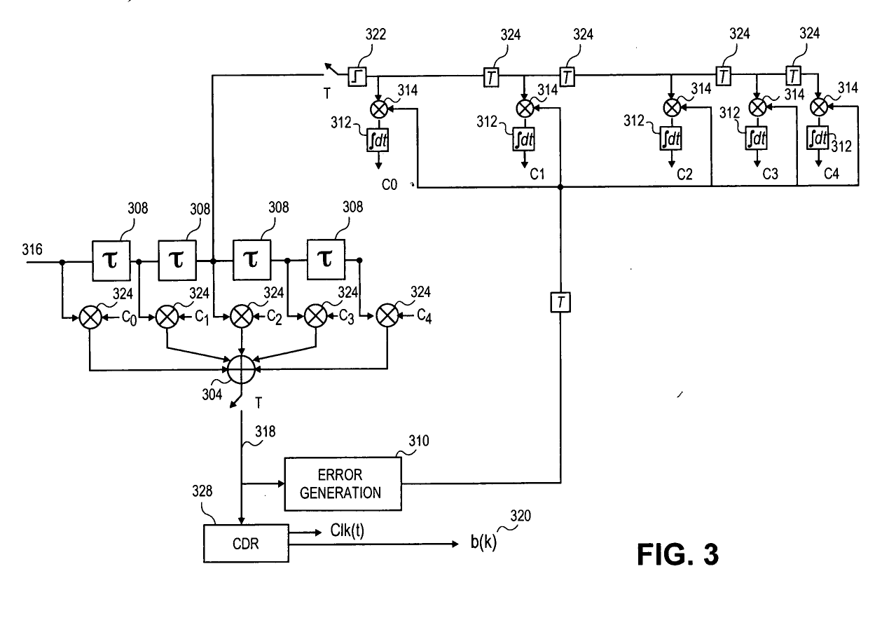

FIG. 3 shows a schematic diagram of a feed forward filter 300 according to an embodiment of the receiver 200 shown in FIG. 3. Analog delay circuits 308 may generate delayed versions or signal taps of an analog input signal received on terminal 316. The analog delay circuits 308 may be formed as described in U.S. patent application Ser. Nos. [Attorney Docket Nos. 042390.P17559 and 042390.P18170] entitled “Analog Delay Circuit,” incorporated herein by reference. The signal taps may be scaled by a coefficient at a corresponding multiplication circuit 312 and a summing circuit 304 may additively combine the outputs of the multiplication circuits 312 to generate an equalized analog output signal 318. In the presently illustrated embodiment, each coefficient may be updated as follows:
cⱼ(k+1)=cⱼ(k)+Δⱼ×sgn[ε(k)]×sgn[bⱼ(k)]
where:
cⱼ(k+1)=the coefficient to scale the jth version of the analog input signal in the future period k+1;
cⱼ(k)=the coefficient to scale the jth version of the analog input signal in the present period k;
sgn[ε(k)]=the sign of the estimated error of the equalized analog output signal in the present period k;
sgn[aⱼ(k)]=the sign of the signal tap of the analog input signal to be scaled by the coefficient cⱼ(k) in the present period k; and
Δⱼ=a predetermined constant.

According to an embodiment, the equalized analog output signal 318 may be received at a CDR circuit 328 to provide recovered symbol information 320 and inter-symbol timing information as a clock signal Clk(t). An error generation circuit 310 may generate the sign of the estimated error of the equalized analog output signal sgn[ε(k)] for the equalized analog output signal in period k based upon the equalized analog output signal 318 and the inter-symbol timing information. For each of the coefficients cⱼ(k) in the present period, a limiting circuit 322 and digital delay elements 324 may generate a corresponding sign of the signal tap of the analog input signal aⱼ(k) to be scaled by the coefficient cⱼ(k). Then, for each of the coefficients cⱼ(k), a corresponding accumulation circuit 312 may update the coefficient cⱼ(k) as the coefficient cⱼ(k+1) to scale aⱼ(k+1) in the future period.

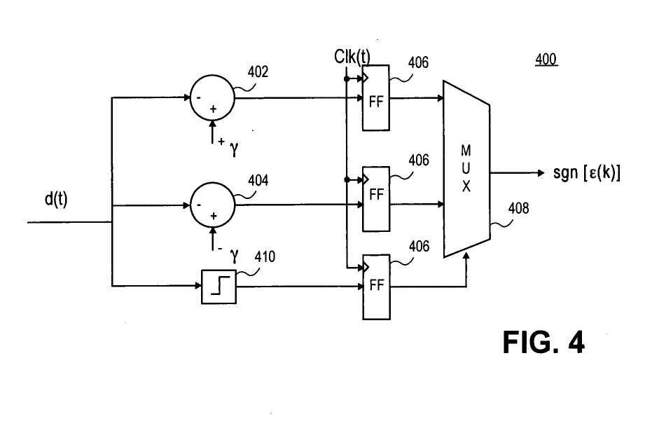

FIG. 4 shows a schematic diagram of a circuit to generate the sign of the estimated error of the filtered analog output signal in the present period k, sgn[ε(k)], according to an embodiment of the error generation circuit 310 shown in FIG. 4. In the presently illustrated embodiment, one of two different symbols may be extracted from the analog input signal in a symbol period, a positive symbol ⁺γ (e.g., a positive voltage) and a negative symbol ⁻γ (e.g., a negative voltage). However these are merely examples of symbols that may be extracted from an analog input signal during a symbol interval and embodiments of the present invention are not limited in this respect.

According to an embodiment, differencing circuits 402 and 404 may receive the equalized analog output signal d(t) to output a difference between the equalized analog output signal d(t) and each of the positive symbol ⁺γ and the negative symbol ⁻γ. A limiting circuit 410 may also receive the equalized analog output signal d(t) to generate an estimate of a symbol value (e.g., between bi-level symbols +1 or −1) encoded in the analog input signal. The outputs of the differencing circuits 402 and 404, and the limiting circuit 410 are applied to inputs of a corresponding flip-flop circuit 406. Each of the flip-flop circuits 406 may also receive pulses of the clock signal Clk(t) to mark a precise instance of when sgn[ε(k)] is to be determined (e.g., the leading edge of Clk(t) pulses to mark an instance in a symbol interval for the detection of a symbol). In response to a setting of the flip-flop circuits 406, a multiplexer (MUX) circuit 408 may receive from the differencing circuit 402 sgn[ε(k)] if the estimate of the symbol value is positive, from the differencing circuit 404 sgn[ε(k)] if the estimate of the symbol value is positive and from the limiting circuit 410 an estimate of the symbol value. Accordingly, based upon the estimate of the symbol value (e.g., as being positive or negative) the MUX 408 may select sgn[ε(k)] as being positive or negative based upon the output of either differencing circuit 402 or differencing circuit 404.

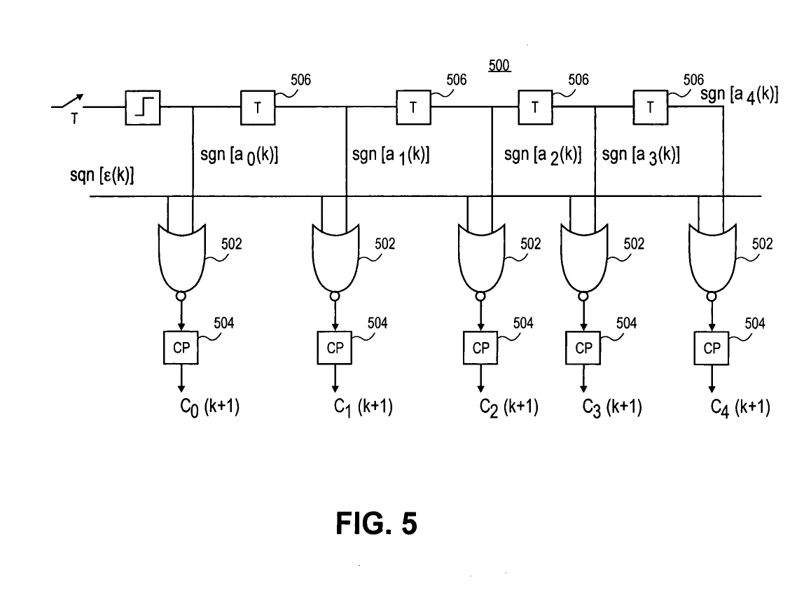

FIG. 5 shows a schematic diagram of a circuit 500 to update coefficients of a multi-tap filter according to an embodiment of the feed forward circuit shown in FIG. 4. According to an embodiment, each of a plurality of NXOR gates 502 employs signed logic to generate an output Δⱼ×sgn[ε(k)]×sgn[aⱼ(k)] from a corresponding charge pump circuit 504 on coefficient update intervals. At one terminal of each NXOR gate 502, the NXOR gate 502 may receive the sign of the estimated error of the filtered analog output signal in the present period k, sgn[ε(k)], as determined according to the embodiment illustrated with reference to FIG. 5. At the other terminal of each NXOR gate 502, the NXOR gate 502 may receive the sign of the version of the signal tap, aⱼ(k), to be scaled by a corresponding coefficient cⱼ(k) in the present period k, sgn[aⱼ(k)]. On a coefficient update interval, each charge pump circuit 504 may receive an output of a corresponding NXOR gate 502, sgn[ε(k)]×sgn[aⱼ(k)], scale the output by Δⱼ, and additively combine with a corresponding coefficient (used to scale the jth signal tap of the analog input signal in the present period k, cⱼ(k)) and provide cⱼ(k+1).

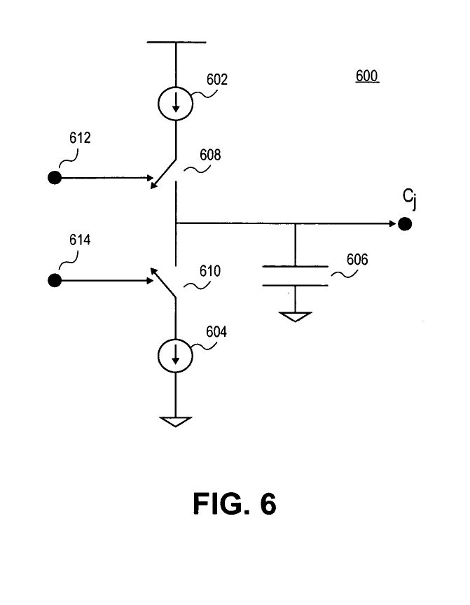

FIG. 6 shows a schematic diagram of a charge pump circuit 600 according to an embodiment of the charge pump circuit 504 circuit shown in FIG. 5. According to an embodiment, switch 608 may couple a current source 602 to add charge to a capacitor 606 in response to a positive value for sgn[ε(k)]×sgn[aⱼ(k)]. Similarly, a switch 610 may couple a current source 604 to remove charge to a capacitor 606 in response to a negative value for sgn[ε(k)]×sgn[aⱼ(k)]. The resulting voltage of capacitor 606 may then represent the updated coefficient cⱼ(k+1).

While there has been illustrated and described what are presently considered to be example embodiments of the present invention, it will be understood by those skilled in the art that various other modifications may be made, and equivalents may be substituted, without departing from the true scope of the invention. Additionally, many modifications may be made to adapt a particular situation to the teachings of the present invention without departing from the central inventive concept described herein. Therefore, it is intended that the present invention not be limited to the particular embodiments disclosed, but that the invention include all embodiments falling within the scope of the appended claims.

1. A receiver comprising:
a multi-tap filter to apply each of a plurality of coefficients to a corresponding tap of an analog input signal to generate an equalized analog signal, the analog input signal comprising a plurality of temporally spaced symbols encoded therein;
a clock and data recovery circuit to recover the temporally spaced symbols and inter-symbol timing information from the equalized analog signal; and
a coefficient update circuit to update the coefficients based, at least in part, upon a comparison of the equalized analog signal with one or more symbol values at an instance determined by the inter-symbol timing information.

2. The receiver of claim 1, wherein for at least one coefficient, the coefficient update circuit further comprises logic to update the coefficient based upon a sign of an error between the equalized analog signal and an estimated symbol value.

3. The receiver of claim 2, wherein the coefficient update circuit further comprises logic to determine the sign of the error based upon a comparison of the equalized analog signal and one or more symbol values at an instance based upon the recovered inter-symbol timing information.

4. The receiver of claim 2, wherein the coefficient update circuit further comprises:
logic to compare the equalized analog signal with each of a plurality of symbol values at an instance based upon the recovered inter-symbol timing information to generate a comparison signal for each of said symbol values;
logic to select a comparison signal based upon the equalized analog signal; and
logic to determine the sign of the error based upon the selected comparison signal.

5. The receiver of claim 2, wherein the coefficient update circuit further comprises logic to update the coefficient based, at least in part, upon the sign of the error and a sign of a corresponding tap of the analog input signal.

6. The receiver of claim 2, wherein the clock and data recover circuit further comprises circuitry to generate clock signal comprising clock signal pulses according to the inter-symbol timing information, and wherein the receiver further comprises logic to detect the sign of the error between the equalized analog signal and the estimated symbol value during symbol intervals on the leading edge of at lease some of the clock signal pulses.

7. The receiver of claim 1, the receiver further comprising:
a circuit to combine each tap of the analog input signal with a corresponding one of the coefficients to provide a scaled signal tap; and
a circuit to sum two or more of the scaled signal taps to provide the equalized analog signal.

8. The receiver of claim 1, the receiver further comprising:
logic to set the coefficients to predetermined values in response to detection of a dynamic condition; and
logic to inhibit the coefficient update circuit from updating the coefficients from the predetermined values for a duration.

9. The receiver of claim 8, the receiver further comprising logic to enable the coefficient update circuit to update the coefficients from the predetermined values in response to recovery of the inter-symbol timing information.

10. The receiver of claim 8, the receiver further comprising logic to enable the coefficient update circuit to update the coefficients from the predetermined values following a duration based upon an estimated time to recover the inter-symbol timing information.

11. A method comprising:
applying each of a plurality of coefficients to a corresponding tap of an analog input signal to generate an equalized analog signal, the analog input signal comprising a plurality of temporally spaced symbols encoded therein;
recovering inter-symbol timing information and the temporally spaced symbols based upon the equalized analog signal; and
updating at least one of the coefficients based, at least in part, upon a comparison of the equalized analog signal with one or more symbol values at an instance determined by the inter-symbol timing information.

12. The method of claim 11, wherein updating the at least one of the coefficients further comprises updating the at least one of the coefficients based upon a sign of an error between the equalized analog signal and an estimated symbol value.

13. The method of claim 12, wherein the method further comprises determining the sign of the error based upon a comparison of the equalized analog signal and one or more symbol values at an instance based upon the recovered inter-symbol timing information.

14. The method of claim 12, wherein updating the at least one of the coefficients further comprises:
comparing the equalized analog signal with each of a plurality of symbol values at an instance based upon the recovered inter-symbol timing information to generate a comparison signal for each of said symbol values;
selecting a comparison signal based upon the equalized analog signal; and
determining the sign of the error based upon the selected comparison signal.

15. The method of claim 12, wherein updating the at least one of the coefficients further comprises updating the coefficient based, at least in part, upon the sign of the error and a sign of a corresponding tap of the analog input signal.

16. The method of claim 12, wherein the method further comprises:
generating a clock signal comprising clock signal pulses according to the inter-symbol timing information; and
detecting the sign of the error between the equalized analog signal and the estimated symbol value during symbol intervals on a leading edge of at least some of the clock signal pulses.

17. The method of claim 1 1, the method further comprising:
combining each tap of the analog input signal with a corresponding one of the coefficients to provide a scaled signal tap; and
summing two or more of the scaled signal taps to provide the equalized analog signal.

18. The method of claim 11, the method further comprising:
setting the coefficients to predetermined values in response to detection of a dynamic condition; and
inhibiting update of the at least one of the coefficients from the predetermined values for a duration.

19. The method of claim 18, method further comprising enabling update of the coefficients from the predetermined values in response to recovery of the inter-symbol timing information.

20. The method of claim 18, the method further comprising enabling update of the coefficients from the predetermined coefficients following a duration based upon an estimated time to recover the inter-symbol timing information.

21. A system comprising:
a receiver adapted to process an analog input signal from a transmission medium, the receiver comprising:
a multi-tap filter to apply each of a plurality of coefficients to a corresponding tap of an analog input signal to generate an equalized analog signal, the analog input signal comprising a plurality of temporally spaced symbols encoded therein;
a clock and data recovery circuit to recover from the equalized analog signal the temporally spaced symbols as a serial data signal and inter-symbol timing information; and
a coefficient update circuit to update the coefficients based, at least in part, upon a comparison of the equalized analog signal with one or more symbol values at an instance determined by the inter-symbol timing information; and
a deserializer to provide a parallel data signal in response to the serial data signal.

22. The system of claim 21, wherein the system further comprises:
a photodiode coupled to an optical transmission medium; and
a transimpedance amplifier to generate the analog input signal in response to a current from the photodiode.

23. The system of claim 21, the system further comprising a SONET framer to receive the parallel data signal.

24. The system of claim 23, wherein the system further comprises a switch fabric coupled to the SONET framer.

25. The system of claim 21, the system further comprising an Ethernet MAC to receive the parallel data signal at a media independent interface.

26. The system of claim 25, wherein the system further comprises a multiplexed data bus coupled to the Ethernet MAC.

27. The system of claim 25, wherein the system further comprises a switch fabric coupled to the Ethernet MAC.
